(19) United States
(12) Patent Application Publication
(10) Pub. No.: US 2007/0187699 A1
(43) Pub. Date: Aug. 16, 2007

(54) LIGHT EMITTING ELEMENT, LIGHT EMITTING DEVICE, AND ELECTRONIC DEVICE

(75) Inventors: Junichiro SAKATA, Atsugi (JP); Yoshiaki YAMAMOTO, Atsugi (JP); Takahiro KAWAKAMI, Isehara (JP); Kohei YOKOYAMA, Ayase (JP); Miki KATAYAMA, Atsugi (JP); Rie MATSUBARA, Isehara (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 11/671,728

(22) Filed: Feb. 6, 2007

(30) Foreign Application Priority Data
Feb. 10, 2006 (JP) 2006-034581

(51) Int. Cl. H01L 33/00

(52) U.S. Cl. 257/79

(57) ABSTRACT

A light emitting element is provided, which comprises a pair of electrodes, a p-type semiconductor layer, and an n-type semiconductor layer. The p-type semiconductor layer and the n-type semiconductor layer are interposed between the pair of electrodes. The p-type semiconductor layer includes a first sulfide, and the n-type semiconductor layer includes a second sulfide. At least one of the p-type semiconductor layer and the n-type semiconductor layer includes a light emitting center.

### TECHNICAL FIELD

The present invention relates to light emitting elements that employ electroluminescence. Further, the present invention relates to light emitting devices and electronic devices that have a light emitting element.

### BACKGROUND ART

In recent years, concerning display devices in televisions, portable telephones, digital cameras and the like, there has been a demand for planar, slim display devices. As display devices which meet this demand, display devices which employ light emitting elements of a self-luminous type have been a focus of attention. An example of a light emitting element of a self-luminous type is a light emitting element utilizing electroluminescence. Such a light emitting element includes a light emitting material interposed between a pair of electrodes, and light emission can be obtained from the light emitting material by applying a voltage.

Compared to a liquid crystal display, such a self-luminous light emitting element has advantages such as the fact that its pixels have high visibility and the fact that it does not need a backlight. Such a self-luminous light emitting element is considered to be suitable for application as a flat panel display element. Further, such light emitting elements have a great advantage in that they can be manufactured slim and lightweight. Furthermore, a feature of such light emitting elements is that they have a very fast response speed.

Moreover, since such self-luminous light emitting elements can be formed as films, by forming elements with a large surface area, plane emission can easily be obtained. Since this is a feature that is hard to obtain in point light sources, typified by incandescent lamps and LEDs, or in line light sources, typified by fluorescent lights, such self-luminous light emitting elements have a high utility value as surface light sources that can be applied to lighting and the like.

Light emitting elements that employ electroluminescence are differentiated by whether their light emitting material is an organic compound or an inorganic compound. Generally, light emitting elements with an organic compound as a light emitting material are called organic EL elements, and light emitting elements with an inorganic compound as a light emitting material are called inorganic EL elements.

Inorganic EL elements are classified into dispersion-type inorganic EL elements and thin-film type inorganic EL elements, according to the structure of the element. These differ in that the former include a light emitting layer in which particles of a light emitting material are dispersed in a binder, and the latter include a light emitting layer formed of a thin film of fluorescent material. However, dispersion-type inorganic EL elements and thin-film type inorganic EL elements have a common mechanism, which is that light emission is obtained by collision excitation of a host material or a light emitting center, which is caused by electrons accelerated by a high electric field. Therefore, in order to obtain light emission from a commonly used inorganic EL element, a high electric field is necessary, and it is necessary to apply a voltage of several hundreds of volts to the light emitting element. For example, in recent years, a high luminance blue light emitting inorganic EL element, which is necessary for a full-color display, has been developed. However, this inorganic EL element requires a drive voltage of 100 to 200 V (for example, see Reference 1: Japanese Journal of Applied Physics, 1999, Vol. 38, pp. L1291-L1292). Therefore, inorganic EL elements have large power consumption, so it has been difficult to use them as medium and small-sized displays, such as displays of portable telephones or the like.

### DISCLOSURE OF INVENTION

In view of the foregoing, an object of the present invention is to provide a light emitting element that is capable of low voltage drive. Further, it is an object of the present invention to provide a light emitting device and an electronic device that have reduced power consumption. Furthermore, it is an object of the present invention to provide a light emitting device and an electronic device that can be manufactured at low cost.

In an aspect of the present invention, a light emitting element includes a pair of electrodes, a p-type semiconductor layer formed of a sulfide in which holes are carriers, and an n-type semiconductor layer formed of a sulfide in which electrons are carriers. The p-type semiconductor layer and the n-type semiconductor layer are interposed between the pair of electrodes. At least one of the p-type semiconductor layer and the n-type semiconductor layer includes an element that forms a light emitting center.

A light emitting element has the above-described structure, and the element that forms a light emitting center is any one of copper, silver and gold.

In a light emitting element having either of the above-described structures, it is preferable that the layer including the light emitting center also includes any one of manganese, samarium, terbium, erbium, thulium, europium, cerium, and praseodymium.

A light emitting element has any one of the above-described structures, and the p-type semiconductor layer includes an impurity element that forms an acceptor level.

A light emitting element has any one of the above-described structures, and the p-type semiconductor layer includes a halogen element.

A light emitting element has any one of the above-described structures, and the p-type semiconductor layer includes Cu₂S as a host material.

A light emitting element has an above-described structure, and the p-type semiconductor layer includes a compound of ZnS and Cu₂S as a host material.

A light emitting element has an above-described structure, and the p-type semiconductor layer is formed of ZnS excessively doped with Cu.

A light emitting element has an above-described structure, and the p-type semiconductor layer is formed of ZnS excessively doped with Ag.

A light emitting element has any one of the above-described structures, and the n-type semiconductor layer is formed of ZnS that includes an impurity element which forms a donor level.

A light emitting element has any one of the above-described structures, and the n-type semiconductor layer includes ZnS as a host material.

A light emitting element has any one of the above-described structures, and the n-type semiconductor layer includes Cu or Ag.

Further, the present invention also includes a light emitting device that includes any one of the above-mentioned light emitting elements. A light emitting device as referred to in this specification includes an image display device, a light emission device, and a light source (including a lighting system). Furthermore, a light emitting device as referred to in this specification also includes a module in which a connector, for example an FPC (flexible printed circuit), TAB (tape automated bonding) tape, or a TCP (tape carrier package), is fitted to a panel including light emitting elements; a module that includes a panel including light emitting elements and in which a printed circuit board is provided at the end of TAB tape or a TCP; and a module in which an IC (integrated circuit) is directly mounted on a panel including light emitting elements by a COG (chip on glass) method.

Further, an electronic device that employs a light emitting element of the present invention in a display portion is also included in the present invention. Therefore, an electronic device of the present invention includes a display portion, and the display portion is equipped with the light emitting element and with a control means that controls the light emission of the light emitting element.

A light emitting element of the present invention is capable of low voltage drive.

Since a light emitting device of the present invention includes a light emitting element capable of low voltage drive, power consumption can be reduced. Further, since the light emitting device does not require a driver circuit with a high withstand voltage, it can be manufactured at low cost.

Since an electronic device of the present invention includes a light emitting element capable of low voltage drive, power consumption can be reduced. Further, since a driver circuit with a high withstand voltage is not necessary, the manufacturing cost of the electronic device can be reduced.

### BRIEF DESCRIPTION OF DRAWINGS

FIG. 1 illustrates a light emitting element of the present invention.

FIG. 2 illustrates a light emitting device of the present invention.

FIGS. 3A and 3B illustrate a light emitting device of the present invention.

FIGS. 4A to 4D illustrate electronic devices of the present invention.

FIG. 5 illustrates an electronic device of the present invention.

### BEST MODE FOR CARRYING OUT THE INVENTION

### Embodiment Modes

Hereinafter, embodiment modes of the present invention will be described below in detail with reference to the accompanying drawings. However, the present invention is not limited to the description below, and those skilled in the art will appreciate that a variety of modifications can be made to the embodiment modes without departing from the spirit and scope of the invention. Accordingly, the present invention should not be construed as being limited to the embodiment modes described below.

### Embodiment Mode 1

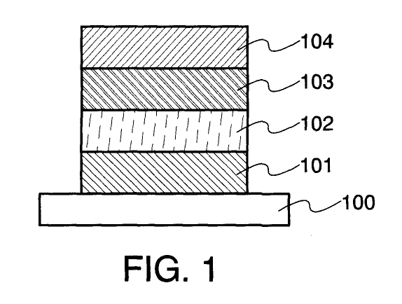

In this embodiment mode, a thin film light emitting element of the present invention will be described with reference to FIG. 1.

A light emitting element described in this embodiment mode has a structure which includes a first electrode 101 and a second electrode 104 which are formed over a first substrate 100. A p-type semiconductor layer 102 and an n-type semiconductor layer 103 are sandwiched between the first electrode 101 and the second electrode 104. Note that in the description of this embodiment mode, the first electrode 101 serves as an anode and the second electrode 104 serves as a cathode.

The substrate 100 is used as a support for the light emitting element. As the substrate 100, glass, quartz, plastic, or the like can be used, for example. Note that as long as the substrate serves as a support for the light emitting element in the manufacturing process, materials other than these can be used for the substrate.

As the first electrode 101 and the second electrode 104, metal, an alloy, a conductive compound, or a mixture of these can be used. Specifically, indium tin oxide (ITO), indium tin oxide containing silicon or silicon oxide, indium zinc oxide (IZO), indium tin oxide containing tungsten oxide and zinc oxide (IWZO), and the like can be used, for example. A conductive metal oxide film of these materials is generally formed by sputtering. For example, indium zinc oxide (IZO) can be formed by sputtering using a target in which zinc oxide is added to indium oxide at 1 to 20 wt %. Further, indium tin oxide containing tungsten oxide and zinc oxide (IWZO) can be formed by sputtering using a target containing 0.5 to 5 wt % tungsten oxide and 0.1 to 1 wt % zinc oxide with respect to indium tin oxide. Besides these materials, aluminum (Al), silver (Ag), gold (Au), platinum (Pt), nickel (Ni), tungsten (W), chromium (Cr), molybdenum (Mo), iron (Fe), cobalt (Co), copper (Cu), palladium (Pd), or a nitride of a metal material (for example, titanium nitride: TiN), or the like can be used. Note that in the case where the first electrode 101 or the second electrode 104 has a light transmitting property, even when a material with a low visible light transmission rate is used, by forming the electrode to a thickness of about 1 nm to 50 nm, preferably about 5 nm to 20 nm, the electrode can be used as a light transmitting electrode. Note that besides sputtering, vacuum evaporation, CVD, or a sol-gel method can also be used to manufacture the electrodes.

Note that concerning light emission, because light passes through either the first electrode 101 or the second electrode 104 to the outside, it is necessary that at least one of the first electrode 101 and the second electrode 104 be formed of a material with a light transmitting property. Further, it is preferable that materials for the electrodes be chosen such that the first electrode 101 has a higher work function than the second electrode 104.

A material that forms the p-type semiconductor layer 102 is a sulfide in which holes are carriers. For example, copper sulfide (Cu₂S), or a mixture of zinc sulfide (ZnS) and copper sulfide can be used. Further, ZnS which is doped with lithium (Li), potassium (K), rubidium (Rb), cesium (Cs), aluminum (Al), gallium (Ga), or indium (In), which are impurity elements that are acceptors, can be used. Furthermore, ZnS excessively doped with Cu or Ag can be used.

A material that forms the n-type semiconductor layer 103 is a sulfide in which electrons are carriers. For example, ZnS or gallium sulfide (Ga₂S₃) can be used. Further, ZnS that is doped with fluorine (F), chlorine (Cl), bromine (Br), iodine (I), nitrogen (N), phosphorus (P), arsenic (As), or antimony (Sb), which are impurity elements that are donors, can be used.

In the present invention, because light emission is obtained from either or both of the p-type semiconductor layer 102 and the n-type semiconductor layer 103, it is necessary to include a light emitting center in either or both of the p-type semiconductor layer 102 and the n-type semiconductor layer 103. Cu, Ag, Au, or the like can be added as a light emitting center. Note that in the case where light emission is to be obtained from the p-type semiconductor layer 102, a halogen element may be added.

Further, as a light emitting center, manganese (Mn), samarium (Sm), terbium (Tb), erbium (Er), thulium (Tm), europium (Eu), cerium (Ce), praseodymium (Pr), or the like may be added. By the addition of these light emitting centers, light emission that employs an inner-shell electron transition of a metal ion can be obtained. Note that as a light emitting center to be added, not only a pure metal element, but a halogen element such as fluorine (F) or chlorine (Cl) may be added, for charge compensation.

In a semiconductor material of the present invention, in the case of using a material doped with an impurity element, the impurity element may be included in a sulfide by using a solid phase reaction; that is to say, a method in which the sulfide and the impurity element are weighed, mixed in a mortar, then reacted by being heated in an electric furnace. The firing temperature is preferably 700 to 1500° C. This is because if the temperature is too low the solid phase reaction will not proceed, and if the temperature is too high, the sulfide will decompose. Note that the firing may be conducted with the mixture in powdered form; however, it is preferable to conduct the firing with the mixture in pellet form.

Further, in the semiconductor material containing a light emitting center, as the impurity element in the case where a solid phase reaction is employed, a compound containing a light emitting center may be employed. In that case, since the impurity element diffuses readily and the solid phase reaction proceeds readily, a semiconductor material in which a light emitting center is included uniformly can be obtained. Further, since excess impurity element does not enter, a light emitting material with high purity can be obtained. For example, copper fluoride (CuF₂), copper chloride (CuCI), copper iodide (CuI), copper bromide (CuBr), copper nitride (Cu₃N), copper phosphide (Cu₃P), silver fluoride (AgF), silver chloride (AgCl), silver iodide (AgI), silver bromide (AgBr), gold chloride (AuCI₃), gold bromide (AuBr₃), or the like can be used.

As a method for forming the p-type semiconductor layer 102 and the n-type semiconductor layer 103, a vacuum evaporation method such as resistive heating evaporation or electron-beam evaporation (EB evaporation), a physical vapor deposition (PVD) method such as sputtering, a metalorganic CVD method, a chemical vapor deposition (CVD) method such as a low pressure hydride transport CVD method, an atomic layer epitaxy method (ALE), or the like can be used. Further, an ink-jet method, a spin-coating method, or the like can be used. There is no particular limitation on the film thickness; however, it is preferably in the 10 to 1000 nm range.

Light emission can be obtained from the p-type semiconductor layer 102 or the n-type semiconductor layer 103 of a light emitting element of the present invention by using direct current drive. However, since hot electrons accelerated by a high electric field are not necessary, a light emitting element that can operate with a low driving voltage can be obtained. Further, since light emission is possible with a low driving voltage, a light emitting element with reduced power consumption can be obtained.

Note that this embodiment mode can be combined as appropriate with other embodiment modes.

### Embodiment Mode 2

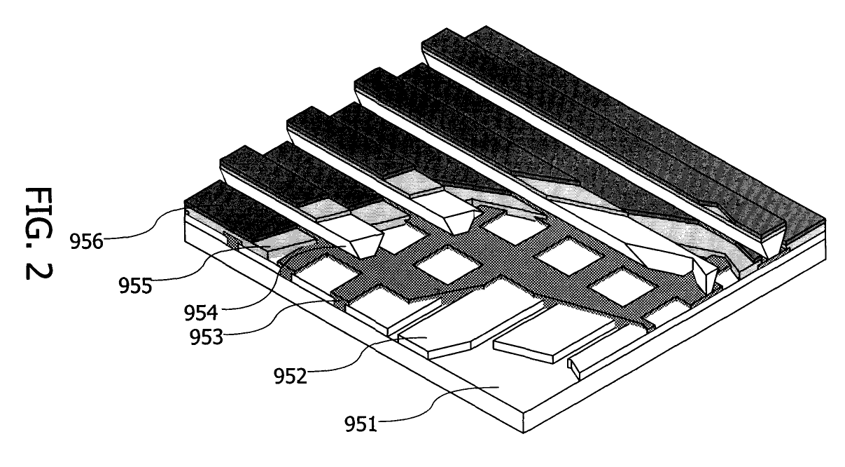

In this embodiment mode, a light emitting device having a light emitting element of the present invention will be described with reference to FIG. 2.

The light emitting device described in this embodiment mode is a passive light emitting device in which a light emitting element is driven without an element for driving, such as a transistor, being provided. FIG. 2 shows a perspective view of a passive light emitting device manufactured applying the present invention.

In FIG. 2, over a substrate 951, a semiconductor layer 955 is provided between an electrode 952 and an electrode 956. Note that the semiconductor layer 955 includes either the stacked layer structure of the p-type semiconductor layer and the n-type semiconductor layer described in Embodiment Mode 1, or a mixed layer of a p-type semiconductor and an n-type semiconductor.

An end portion of the electrode 952 is covered by an insulating layer 953. Further, over the insulating layer 953, a partition wall layer 954 is provided. Side walls of the partition wall layer 954 have a slant such that the closer to a surface of the substrate, the narrower the distance between one side wall and the other. That is, a cross-section taken along the direction of a shorter side of the partition wall layer 954 has a trapezoidal shape, and the base of the trapezoid (a side of the trapezoid that is in contact with the insulating layer 953) is shorter than the upper side of the trapezoid (a side of the trapezoid that is not in contact with the insulating layer 953). By providing the partition wall layer 954 in this manner, defects in the light emitting element caused by static electricity and the like can be prevented. Further, a light emitting element can be driven with low power consumption in a passive light emitting device by including the light emitting element of the present invention, which operates with a low driving voltage.

Further, since a light emitting device of the present invention does not require a driver circuit with a high withstand voltage, the manufacturing cost of the light emitting device can be reduced. Moreover, the weight of the light emitting device can be reduced, and the driver circuit portion can be made smaller.

### Embodiment Mode 3

In this embodiment mode, a light emitting device having a light emitting element of the present invention will be described.

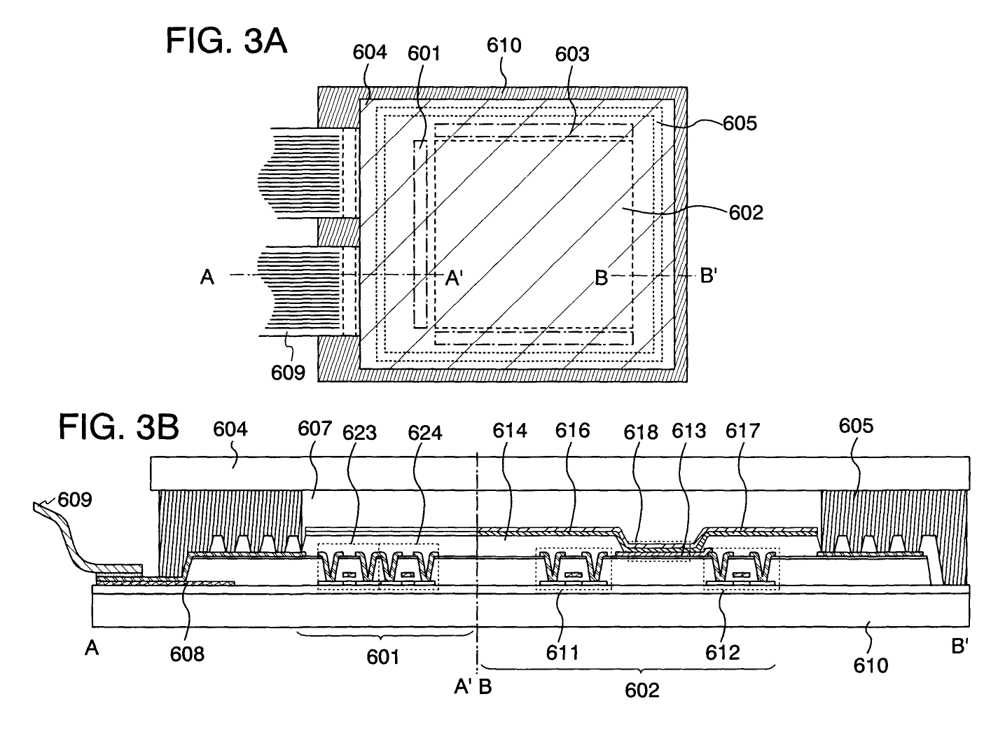

In this embodiment mode, an active light emitting device in which the drive of a light emitting element is controlled by a transistor will be described. In this embodiment mode, a light emitting device that includes the light emitting element of the present invention in a pixel portion will be described with reference to FIGS. 3A and 3B. Note that FIG. 3A is a top view of the light emitting device, and FIG. 3B shows cross-sections taken along lines A-A′ and B-B′ of FIG. 3A. Concerning the reference numerals for the areas shown by dotted lines, 601 denotes a driver circuit portion (a source side driver circuit), 602 denotes the pixel portion, and 603 denotes a driver circuit portion (a gate side driver circuit). Further, reference numeral 604 denotes a sealing substrate, reference numeral 605 denotes a sealant, and an area enclosed by the sealant 605 is a space 607.

Further, a lead wire 608 transmits signals input to the source side driver circuit 601 and the gate side driver circuit 603, and receives video signals, clock signals, start signals, reset signals, and the like from an FPC (flexible printed circuit) 609 which is an external input terminal. Note that a printed wiring board (PWB) may be attached to the FPC, although only the FPC is shown in the drawings. In this specification, ‘light emitting device’ refers not only to the body of a light emitting device, but also to the body of a light emitting device fitted with an FPC or a PWB.

Next, a cross-sectional structure will be described with reference to FIG. 3B. Over an element substrate 610, driver circuit portions and a pixel portion are formed. Here, the source side driver circuit 601, which is a driver circuit portion, and one pixel in the pixel portion 602 are shown.

Note that a CMOS circuit in which an n-channel TFT 623 and a p-channel TFT 624 are combined is formed as the source side driver circuit 601. The driver circuit may be a known CMOS circuit, a PMOS circuit, or an NMOS circuit. Furthermore, in this embodiment mode, a driver-integrated type structure in which the driver circuit is formed over the substrate is described, but a driver-integrated type structure is not necessarily required. A driver circuit can be formed external to the substrate, rather than over the substrate.

Further, the pixel portion 602 includes a plurality of pixels, which include a switching TFT 611, a current controlling TFT 612, and a first electrode 613 which is electrically connected to a drain of the current controlling TFT 612. Note that an insulator 614 is formed so as to cover an end portion of the first electrode 613. Here, the insulator is formed using a positive photosensitive acrylic resin film.

Further, to make coatability good, either an upper end portion or a lower end portion of the insulator 614 is formed such that it has a curved surface having a curvature. For example, in the case of using a positive photosensitive acrylic as a material for the insulator 614, it is preferable to give only the upper end portion of the insulator 614 a curved surface, having a curvature radius (of 0.2 to 3 μm). Further, as the insulator 614, either a negative material, which becomes insoluble in etchant when irradiated with light, or a positive material, which becomes soluble in etchant when irradiated with light, can be used.

Over the first electrode 613, a semiconductor layer 616 containing a p-type semiconductor layer and an n-type semiconductor layer, and a second electrode 617 are formed. At least one of either the first electrode 613 and the second electrode 617 has a light transmitting property, and can let light emitted from the semiconductor layer 616 pass to the outside.

Note that various methods can be used to form the first electrode 613, the semiconductor layer 616 containing a p-type semiconductor layer and an n-type semiconductor layer, and the second electrode 617. Specifically, a vacuum evaporation method such as a resistive heating evaporation method or an electron-beam evaporation (EB evaporation) method, a physical vapor deposition (PVD) method such as sputtering, a metalorganic CVD method, a chemical vapor deposition (CVD) method such as a low pressure hydride transport CVD method, an atomic layer epitaxy method (ALE), or the like can be used. Further, an ink-jet method, a spin-coating method, or the like can be used. Moreover, different film formation methods may be used to form each electrode and to form each layer.

Furthermore, by affixing the sealing substrate 604 to the element substrate 610 with the sealant 605, a structure is obtained in which a light emitting element 618 is provided in the space 607 which is surrounded by the element substrate 610, the sealing substrate 604, and the sealant 605. Note that the space 607 is filled with a filler. Besides the case where the space 607 is filled with an inert gas (such as nitrogen, argon, or the like), there are also cases where it is filled with the sealant 605.

Note that an epoxy-based resin is preferably used as the sealant 605. Further, it is desirable that materials used for the sealant 605 be materials which transmit as little water and oxygen as possible. Further, as a material used for the sealing substrate 604, besides a glass substrate or a quartz substrate, a plastic substrate formed of FRP (fiberglass-reinforced plastic), PVF (polyvinyl fluoride), Mylar, polyester, acrylic, or the like can be used.

In the above manner, a light emitting device having a light emitting element of the present invention can be obtained.

Since a light emitting device of the present invention has the light emitting element described in Embodiment Mode 1, it can operate with a low driving voltage. Further, a light emitting device of the present invention can realize high luminous efficiency. Therefore, a light emitting device with reduced power consumption can be obtained.

Further, since the light emitting device of the present invention does not require a driver circuit with a high withstand voltage, the manufacturing cost of the light emitting device can be reduced. Moreover, the weight of the light emitting device can be reduced, and a driver circuit portion can be made smaller.

### Embodiment Mode 4

In this embodiment mode, an electronic device of the present invention which includes the light emitting device described in Embodiment Mode 3 will be described. The electronic device of the present invention includes the light emitting element described in Embodiment Mode 1. Therefore, an electronic device with reduced power consumption can be provided, since the electronic device includes a light emitting element with reduced drive voltage.

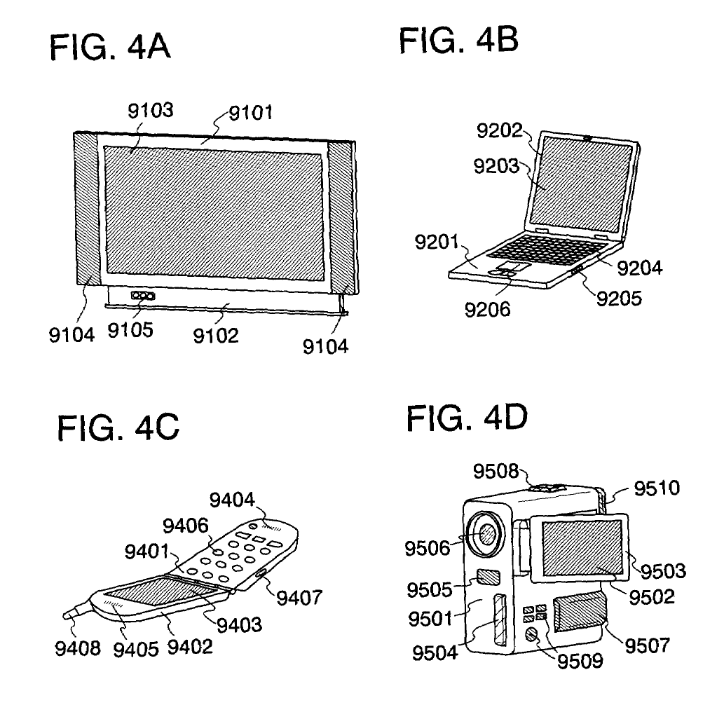

As examples of electronic devices manufactured using the light emitting device of the present invention, a camera such as a video camera or a digital camera, a goggle-type display, a navigation system, a sound reproduction device (such as a car audio device, or an audio component), a computer, a game machine, a portable information terminal (such as a mobile computer, a portable telephone, a portable game machine, or an electronic book), an image reproduction device equipped with a recording medium (specifically, a device for reproducing a recording medium such as a digital versatile disc (DVD) and having a display for displaying the image), and the like can be given. Some specific examples of such electronic devices are shown in FIGS. 4A to 4D.

FIG. 4A shows a television device according to the present invention that includes a housing 9101, a support 9102, a display portion 9103, speaker portions 9104, a video input terminal 9105, and the like. The display portion 9103 of the television device includes light emitting elements similar to those described in Embodiment Modes 2 and 3, that are arranged in a matrix. The light emitting elements have the features of high luminous efficiency and low driving voltage. Further, the light emitting elements can prevent short circuits which occur due to external impact or the like. The display portion 9103 which includes the light emitting elements also has these features. Accordingly, the television device has less deterioration of image quality and consumes less power. Thanks to these features, deterioration compensation functions and power supply circuits in the television device can be considerably cut back or reduced in size. Therefore, the housing 9101 and the support 9102 can be made smaller and lighter. A television device according to the present invention has low power consumption, high image quality, and reduced size and weight. Therefore, a product which is suited to a living environment can be provided.

FIG. 4B shows a computer according to the present invention that includes a main body 9201, a housing 9202, a display portion 9203, a keyboard 9204, an external connection port 9205, a touchpad 9206, and the like. The display portion 9203 of the computer includes light emitting elements similar to those described in Embodiment Modes 2 and 3, that are arranged in a matrix. The light emitting elements have the features of high luminous efficiency and low driving voltage. Further, they can prevent short circuits which occur due to external impact or the like. The display portion 9203 which includes the light emitting elements also has these features. Accordingly, the computer has less deterioration of image quality and consumes less power. Thanks to these features, deterioration compensation functions and power supply circuits in the computer can be considerably cut back or reduced in size. Therefore, the main body 9201 and the housing 9202 can be made smaller and lighter. A computer according to the present invention has low power consumption, high image quality, and reduced size and weight, so a product which is suited to an environment can be provided. Further, the computer can be portable. Accordingly, a computer having a display portion which can well withstand external impacts that occur when the computer is being carried can be provided.

FIG. 4C shows a portable telephone according to the present invention that includes a main body 9401, a housing 9402, a display portion 9403, an audio input portion 9404, an audio output portion 9405, operation keys 9406, an external connection port 9407, an antenna 9408, and the like. The display portion 9403 of the portable telephone includes light emitting elements similar to those described in Embodiment Modes 2 and 3, that are arranged in a matrix. The light emitting elements have the features of high luminous efficiency and low driving voltage. Further, they can prevent short circuits which occur due to external impact or the like. The display portion 9403 which includes the light emitting elements also has these features. Accordingly, the portable telephone has less deterioration of image quality and consumes less power. Thanks to these features, deterioration compensation functions and power supply circuits in the portable telephone can be considerably cut back or reduced in size. Therefore, the main body 9401 and the housing 9402 can be made smaller and lighter. A portable telephone according to the present invention has low power consumption, high image quality, and reduced size and weight, so a product which is suited to being carried can be provided. Further, a product having a display portion which can well withstand external impacts that occur when the product is being carried can be provided.

FIG. 4D shows a camera according to the present invention. The camera includes a main body 9501, a display portion 9502, a housing 9503, an external connection port 9504, a remote control receiver portion 9505, an image receiving portion 9506, a battery 9507, an audio input portion 9508, operation keys 9509, an eyepiece portion 9510, and the like. The display portion 9502 of the camera includes light emitting elements similar to those described in Embodiment Modes 2 and 3, that are arranged in a matrix. The light emitting elements have the features of high luminous efficiency and low driving voltage. Further, they can prevent short circuits which occur due to external impact or the like. The display portion 9502 which includes the light emitting elements also has these features. Accordingly, the camera has less deterioration of image quality and consumes less power. Thanks to such features, deterioration compensation functions and power supply circuits in the camera can be considerably cut back or reduced in size. Therefore, the main body 9501 can be made smaller and lighter. A camera according to the present invention has low power consumption, high image quality, and reduced size and weight, so a product which is suited to being carried can be provided. Further, a product having a display portion which can well withstand external impacts that occur when the product is being carried can be provided.

As described above, the range of application of a light emitting device of the present invention is extremely wide. The light emitting device can be applied to electronic devices in all kinds of fields. By using the light emitting device of the present invention, an electronic device having a display portion that has low power consumption and high reliability can be provided.

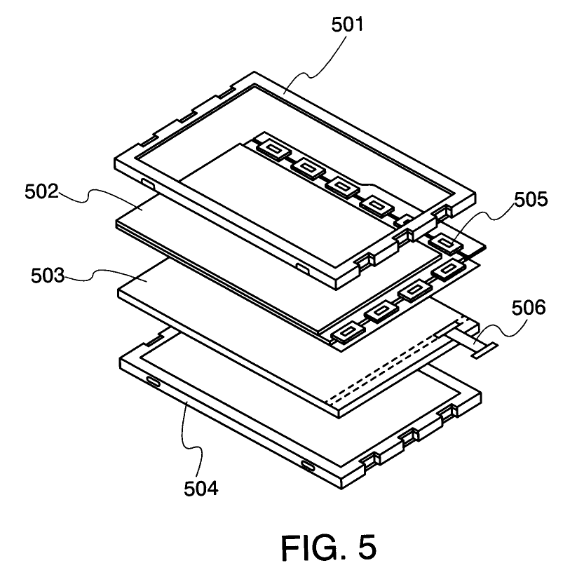

Further, a light emitting device of the present invention has a light emitting element with high luminous efficiency, and can also be used as a lighting system. One mode of using a light emitting element of the present invention as a lighting system will be described with reference to FIG. 5.

FIG. 5 shows an example of a liquid crystal display device that uses a light emitting device of the present invention as a backlight. The liquid crystal display device shown in FIG. 5 includes a housing 501, a liquid crystal layer 502, a backlight 503, and a housing 504. The liquid crystal layer 502 is connected to a driver IC 505. Further, the backlight 503 employs a light emitting device of the present invention, and is supplied with current by a terminal 506.

By using a light emitting device of the present invention as a backlight of a liquid crystal display device, a backlight with reduced power consumption can be obtained. Further, since a light emitting device of the present invention is a plane emission lighting system and can have a large surface area, the backlight can have a large surface area, so the liquid crystal display device can also have a large surface area. Further, since the light emitting device is slim and has low power consumption, the display device can be made slimmer and can have reduced power consumption.

The present application is based on Japanese Priority application No. 2006-034581 filed on Feb. 10, 2006 with the Japanese Patent Office, the entire contents of which are hereby incorporated by reference.

1. A light emitting element comprising:
a pair of electrodes; and
a p-type semiconductor layer and an n-type semiconductor layer interposed between the pair of electrodes,
wherein the p-type semiconductor layer includes a first sulfide,
wherein the n-type semiconductor layer includes a second sulfide, and
wherein at least one of the p-type semiconductor layer and the n-type semiconductor layer includes a light emitting center.

2. The light emitting element according to claim 1, wherein the light emitting center is at least one selected from the group consisting of copper, silver, and gold.

3. The light emitting element according to claim 1, wherein the light emitting center includes a first element and a second element, wherein the first element is at least one selected from the group consisting of copper, silver, and gold, and wherein the second element is at least one selected from the group consisting of manganese, samarium, terbium, erbium, thulium, europium, cerium, and praseodymium.

4. The light emitting element according to claim 1, wherein the p-type semiconductor layer further includes a halogen element when the p-type semiconductor layer includes the light emitting center.

5. A light emitting element comprising:
a pair of electrodes; and
a p-type semiconductor layer and an n-type semiconductor layer interposed between the pair of electrodes,
wherein the p-type semiconductor layer includes a first sulfide,
wherein the n-type semiconductor layer includes a second sulfide,
wherein at least one of the p-type semiconductor layer and the n-type semiconductor layer includes a light emitting center,
wherein the first sulfide is at least one selected from the group consisting of copper sulfide, zinc sulfide, and zinc sulfide doped with an impurity element, and
wherein the second sulfide is at least one selected from the group consisting of zinc sulfide, gallium sulfide, and zinc sulfide doped with an impurity element.

6. The light emitting element according to claim 5, wherein the light emitting center is at least one selected from the group consisting of copper, silver, and gold.

7. The light emitting element according to claim 5, wherein the light emitting center includes a first element and a second element, wherein the first element is at least one selected from the group consisting of copper, silver, and gold, and wherein the second element is at least one selected from the group consisting of manganese, samarium, terbium, erbium, thulium, europium, cerium, and praseodymium.

8. The light emitting element according to claim 5, wherein the p-type semiconductor layer further includes a halogen element when the p-type semiconductor layer includes the light emitting center.

9. The light emitting element according to claim 5, wherein the impurity element included in the p-type semiconductor layer is an acceptor.

10. The light emitting element according to claim 5, wherein the impurity element included in the p-type semiconductor layer is at least one selected from the group consisting of lithium, potassium, rubidium, cesium, aluminum, gallium, indium, copper, and silver.

11. The light emitting element according to claim 5, wherein the impurity element included in the n-type semiconductor layer is a donor.

12. The light emitting element according to claim 5, wherein the impurity element included in the n-type semiconductor layer is at least one selected from the group consisting of fluorine, chlorine, bromine, iodine, nitrogen, phosphorus, arsenic, and antimony.

13. The light emitting element according to claim 5, wherein the impurity element included in the p-type semiconductor layer is different from the impurity element included in the n-type semiconductor layer.

14. A light emitting device including at least one light emitting element,
the light emitting element comprising:
a pair of electrodes; and
a p-type semiconductor layer and an n-type semiconductor layer interposed between the pair of electrodes,
wherein the p-type semiconductor layer includes a first sulfide,
wherein the n-type semiconductor layer includes a second sulfide, and
wherein at least one of the p-type semiconductor layer and the n-type semiconductor layer includes a light emitting center.

15. An electronic device comprising a display portion, wherein the display portion comprises the light emitting device according to claim 14.

16. A light emitting device including at least one light emitting element,
the light emitting element comprising:
a pair of electrodes; and
a p-type semiconductor layer and an n-type semiconductor layer interposed between the pair of electrodes,
wherein the p-type semiconductor layer includes a first sulfide,
wherein the n-type semiconductor layer includes a second sulfide,
wherein at least one of the p-type semiconductor layer and the n-type semiconductor layer includes a light emitting center,
wherein the first sulfide is at least one selected from the group consisting of copper sulfide, zinc sulfide, and zinc sulfide doped with an impurity element, and
wherein the second sulfide is at least one selected from the group consisting of zinc sulfide, gallium sulfide, and zinc sulfide with an impurity element.

17. An electronic device comprising a display portion, wherein the display portion comprises the light emitting device according to claim 16.
